(19) United States
(12) Patent Application Publication
(10) Pub. No.: US 2006/0104325 A1
(43) Pub. Date: May 18, 2006

(54) Laser diode and method of fabricating the same

(75) Inventor: Dae-ho Lim, Suwon-si (KR)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: Samsung Electronics Co., Ltd., Suwon-si (KR)

(21) Appl. No.: 11/220,707

(22) Filed: Sep. 8, 2005

(30) Foreign Application Priority Data
Oct. 19, 2004 (KR) 10-2004-0083582

(51) Int. Cl. H01S 5/00

(52) U.S. Cl. 372/43.01

(57) ABSTRACT

A laser diode without a ridge and a method of fabricating the same are provided. The laser diode includes an active layer and upper and lower clad layers. A current blocking layer formed of a semiconductor material is formed on the upper clad layer, and a current passing region is formed using doping through the current blocking layer. The current passing region diffuses down into the upper clad layer. Since the laser diode includes no ridge, it can be fabricated in a simple fabrication process at a low production cost.

### CROSS-REFERENCE TO RELATED PATENT APPLICATION

This application claims the benefit of Korean Patent Application No. 10-2004-0083582, filed on Oct. 19, 2004, in the Korean Intellectual Property Office, the disclosure of which is incorporated herein in its entirety by reference.

### BACKGROUND OF THE DISCLOSURE

1. Field of the Disclosure

The disclosure relates to a laser diode and a method of fabricating the same, more particularly, to a laser diode, which is structurally simple and fabricated in a simple process, and a method of fabricating the same.

2. Description of the Related Art

In general, a ridge waveguide laser diode has a ridge structure in which the injection of current into a top portion of a crystalline layer is locally restrained. The ridge structure is typically formed in an upper clad layer, and a passivation layer or current blocking layer is formed on both sides of the ridge structure to block current flow.

An example of a conventional nitride semiconductor laser device will now be described.

Referring to FIG. 1, an n-GaN lower contact layer 12 is stacked on a sapphire substrate 10. The n-GaN lower contact layer 12 is divided into a first region R1 and a second region R2. A multiple semiconductor material layer is disposed as a mesa structure on the lower contact layer 12. Specifically, an n-GaN/AlGaN lower clad layer 24, an n-GaN lower waveguide layer 26, an InGaN active layer 28, a p-GaN upper waveguide layer 30, and a p-GaN/AlGaN upper clad layer 32 are sequentially stacked on a top surface of the n-GaN lower contact layer 12 in the first region R1. In this case, the refractive indexes of the n- and p-GaN/AlGaN lower and upper clad layers 24 and 32 are lower than those of the n- and p-GaN lower and upper waveguide layers 26 and 30, respectively, and each of the refractive indexes of the n- and p-GaN lower and upper waveguide layers 26 and 30 is lower than that of the InGaN active layer 28. In this mesa structure, a protruding ridge 32a with a predetermined width, which provides a ridge waveguide structure, is disposed on a top central portion of the p-GaN/AlGaN upper clad layer 32, and a p-GaN upper contact layer 34 is disposed on a top surface of the ridge 32a. A buried layer 36 having a contact hole 36a is disposed as a passivation layer on the p-GaN/AlGaN upper clad layer 32. The contact hole 36a disposed in the buried layer 36 corresponds to a top portion of the upper contact layer 34 disposed on the top surface of the ridge 32a, and an edge portion of the contact hole 36a overlaps an edge portion of a top surface of the upper contact layer 34.

A p-type upper electrode 38 is disposed on the buried layer 36 such that it contacts the upper contact layer 34 through the contact hole 36a disposed in the buried layer 36. An n-type lower electrode 37 is disposed on the second region R2 of the n-GaN lower contact layer 12, which forms a lower top surface than the first region R1.

The ridge waveguide structure, which is prepared on the upper clad layer 32, restricts the flow of current into the active layer 28 so that a resonant region of the active layer 28 for laser oscillation is limited in width to stabilize a transverse mode and reduce an operating current.

Fabrication of the above-described conventional nitride semiconductor laser device involves forming a multiple GaN-based semiconductor material layer corresponding to a pair of unit devices on a sapphire substrate 10 as shown FIG. 2 forming a ridge 32a corresponding to a current injection region using dry etching, and performing a facet etching process to form a mesa structure on an n-GaN lower contact layer 12 so that the n-GaN lower contact layer 12 is exposed and a facet surface is formed along A-A′ line. The facet etching process should be followed by formation of a buried layer on both sides of the ridge 32a and formation of a contact hole corresponding to a top portion of the ridge in the buried layer.

As described above, since a conventional laser diode makes use of a ridge to restrict the flow of current, its fabrication involves complicated process operations of during formation, for example, the presence of the ridge, a buried layer, and a contact hole to constrain the injection of current into the ridge. In various aspects, there is a strong need for research to minimize of the complicated process operations as much as possible.

### SUMMARY OF THE DISCLOSURE

The present invention may provide a laser diode with a new-type of current injection structure and a method of fabricating the same.

The present invention also provides a laser diode, which is fabricated in a simple process at a low production cost, and a method of fabricating the same.

According to an aspect of the present invention, there may be provided a laser diode, which includes a crystalline layer disposed on a substrate, the crystalline layer in which a sandwich of an upper clad layer and a lower clad layer is separated by a laser resonant layer; a current blocking layer disposed on the crystalline layer; and an impurity current passing region disposed through respective portions of the current blocking layer and the upper clad layer.

According to another aspect of the present invention, there may be provided a method of fabricating a laser diode. The method includes forming a crystalline layer on a substrate, the crystalline layer in which a sandwich of an upper clad layer and a lower clad layer is separated by a resonant layer; forming a current blocking layer on the crystalline layer; and forming a current passing region through respective portions of the current blocking layer and the upper clad layer.

### BRIEF DESCRIPTION OF THE DRAWINGS

The above and other features and advantages of the present invention will become more apparent by describing in detail exemplary embodiments thereof with reference to the attached drawings in which:

FIG. 1 is a cross-sectional view of a conventional semiconductor laser device;

FIG. 2 is a plan view of a substrate illustrating an operation for fabricating a conventional semiconductor laser device, in which unit laser devices are not separated from each other;

FIG. 3 is a cross-sectional view of a laser diode according to the present invention; and

FIGS. 4A through 7 are cross-sectional views illustrating exemplary operations for fabricating a laser diode according to the present invention.

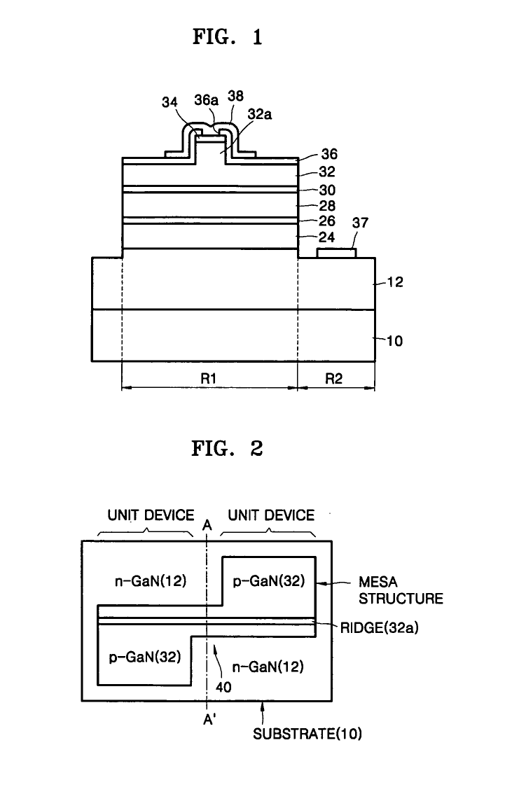

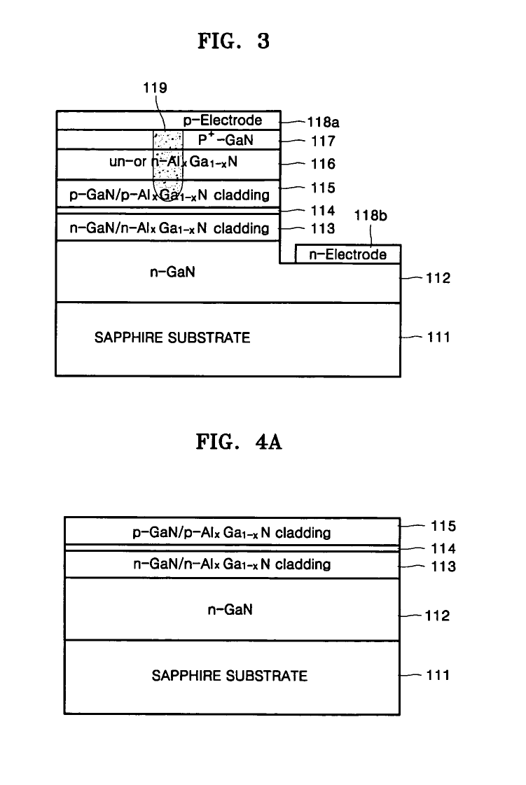

### DETAILED DESCRIPTION OF EXEMPLARY EMBODIMENTS

The present invention will now be described more fully hereinafter with reference to the accompanying drawings, in which exemplary embodiments of the invention are shown.

Referring to FIG. 3, an n-GaN lower contact layer 112 may be stacked on a sapphire substrate 111. An n-type lower electrode 118b may be disposed on a portion of the lower contact layer 112, and a mesa structure may be disposed using a multiple semiconductor material layer on the other portion thereof. That is, an n-GaN/AlGaN lower clad layer 113, an InGaN active layer 114, and a p-GaN/AlGaN upper clad layer 115 are sequentially stacked on a top surface of the n-GaN lower contact layer 112. In the above-described structure, an upper waveguide layer and a lower waveguide layer, which are prepared on and under the active layer 114, are omitted here to simplify the explanation.

In the mesa structure, the p-GaN/AlGaN upper clad layer 115 has a planar top surface on which a current blocking layer 116 is formed using a semiconductor material. The present invention is characterized by the current blocking layer 116. In addition, the present invention is also characterized by a current passing region 119, which is formed on the current blocking layer 116 through the diffusion or injection of impurity ions. The current passing region 119 extends to the upper clad layer 115 by diffusion of impurity ions. The current blocking layer 116 may be formed of a material having a reverse polarity to the p-CaN/AlGaN upper clad layer 115, for example, n-AlGaN. Thus, the current blocking layer 116 serves as a current blocking barrier for blocking current flow between the upper clad layer 115 and a p⁺-GaN contact layer 117. In another embodiment, the current blocking layer 116 may be formed of a semiconductor material having a very high electric resistance, for example, undoped AlGaN. Some materials have n- or p-type physical properties while they are being undoped. For the present invention, the current blocking layer 116 at least must not have the same polarity as the upper clad layer 115. In other words, it will be understood that the current blocking layer 116 should not be a p-type layer, as might be the case in forming a p-type upper clad layer, and should not be an n-type layer, as might be the case in forming an n-type upper clad layer. The current passing region 119 is about 0.5 to about 50 microns in width.

The current passing region 119 extends also into the sufficiently doped p⁺-GaN contact layer 117. An upper electrode 118a is disposed over the current blocking layer 116.

Since the above-described laser diode according to the present invention does not have a conventional ridge structure, the fabrication of such ridge structure is unnecessary. The present invention constrains the injection of current through a high resistance or a current blocking barrier and allows the supply of current to the active layer 114 through a highly conductive diffusion (or implantation) region (i.e., the current passing region 119). The laser diode of the present invention has a gain waveguide structure in place of the conventional ridge waveguide structure.

Hereinafter, exemplary operations for fabricating a laser diode according to the present invention will be described.

Formation of a Crystalline Layer for a Laser Diode

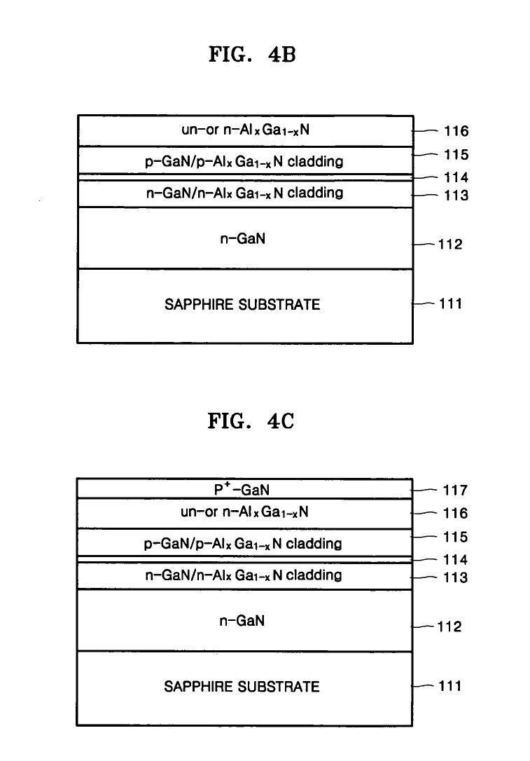

Referring to FIG. 4A, an n-GaN lower contact layer 112, a GaN-based III-V group nitride compound semiconductor layer 114 as an active layer formed of InₓAl_{y}Ga_{1-x-y}N(0≦x≦1, 0≦y≦1x+y≦1), and a p-GaN/AlGaN upper clad layer 115 are sequentially grown on a sapphire substrate 111 by a known method.

Referring to FIG. 4B, a current blocking layer 116 for blocking the flow of current is formed on the upper clad layer 115. The current blocking layer 116 is formed of undoped AlGaN (un-AlGaN) or doped n-GaN.

Referring to FIG. 4C, a sufficiently doped p⁺-GaN contact layer 117 is formed over the current blocking layer 115.

Formation of a Current Passing Region

The formation of the current passing region can be performed using a diffusion process or an impurity implantation process as described below.

1. Diffusion

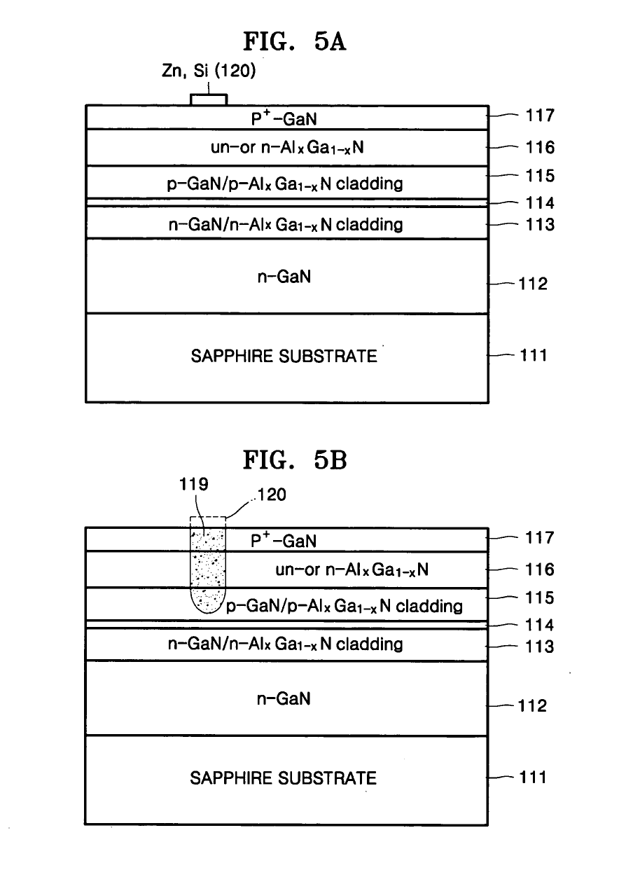

Referring to FIG. 5A, a Zn (or Si) diffusion material layer 120 for forming a current passing region 119 is formed on the contact layer 117. The position of the diffusion material layer 120 substantially corresponds to the position of a conventional ridge.

Referring to FIG. 5B, an annealing process is carried out in a furnace so that the diffusion material layer 120 diffuses into the underlying semiconductor material layer. In this case, the diffusion material layer 120 thermally diffuses into a portion of the underlying semiconductor material layer in a vertical direction, thus the current passing region 119 is formed from the contact layer 117 to the upper clad layer 115.

2. Implantation

Referring to FIG. 6, Zn (or Si) ions are implanted into a top surface of the crystalline layer down to the upper clad layer 115 using an ion implantation apparatus, thereby forming the current passing region 119.

Formation of a Mesa Structure and Electrodes

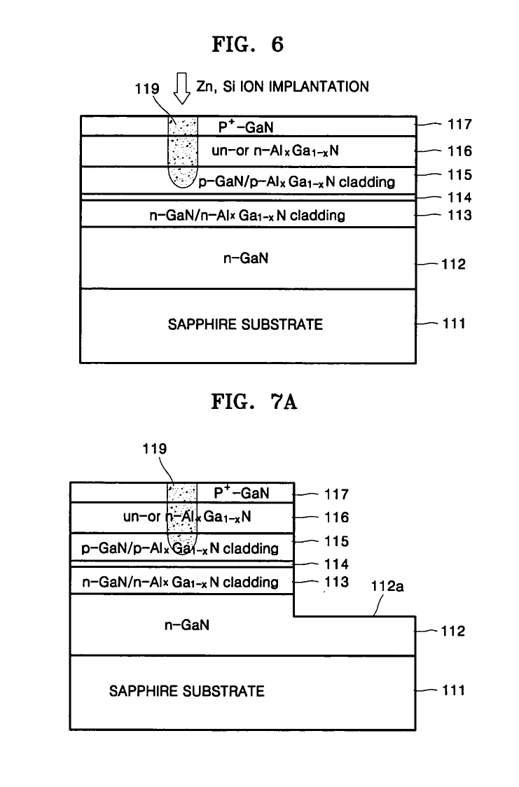

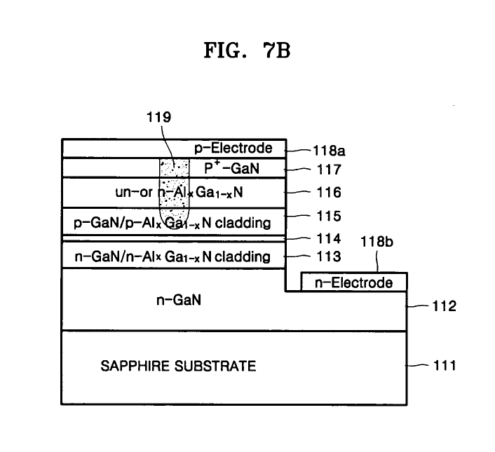

Referring to FIG. 7A, the above-described stacked structure is patterned so that a mesa structure with a multiple semiconductor stacked layer and a stepped portion 112a are obtained. The stepped portion 112a is formed in the lower contact layer 112.

Referring to FIG. 7B, an upper electrode 118a and a lower electrode 118b are formed on the mesa structure (i.e., on the upper contact layer 117) and the lower contact layer 112, respectively.

As explained thus far, the present invention does not involve the formation of a ridge and the formation of electrodes using patterns, which are utilized in a conventional method. Thus, a laser diode can be fabricated using a monolithic growth process, which is performed in a more straightforward manner than the conventional method. Also, the laser diode of the present invention has no ridge so that a top surface of a crystalline layer generally is planar.

According to the method of the present invention, a current injection region can be effectively controlled as [to] an active layer through the adjustment of the size of a material pattern or an ion implantation region. The control of the current injection region facilitates ideal single transverse-mode oscillation of the laser diode.

The method of the present invention can be applied to laser diodes formed of various materials, such as an AlGaN-based laser diode or an InGaAlP-based laser diode.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A laser diode comprising:
a crystalline layer disposed on a substrate, the crystalline layer in which a sandwich of an upper clad layer and a lower clad layer is separated by a laser resonant layer;
a current blocking layer disposed on the crystalline layer; and
an impurity current passing region disposed through respective portions of the current blocking layer and the upper clad layer.

2. The laser diode of claim 1, wherein the current blocking layer is an undoped semiconductor material layer.

3. The laser diode of claim 1, wherein the current blocking layer is a semiconductor material layer, which is doped with a material having a reverse polarity to the upper clad layer.

4. The laser diode of claim 3, wherein the current blocking layer is doped with one of Zn and Si ions.

5. The laser diode of claim 1, further comprising a contact layer and an upper electrode, which are sequentially stacked on the current blocking layer.

6. The laser diode of claim 1, wherein the crystalline layer is formed of one of an AlGaN-based material and an InGaAlP-based material.

7. A method of fabricating a laser diode, the method comprising:
forming a crystalline layer on a substrate, the crystalline layer in which a sandwich of an upper clad layer and a lower clad layer is separated by a resonant layer;
forming a current blocking layer on the crystalline layer; and
forming a current passing region through respective portions of the current blocking layer and the upper clad layer.

8. The method of claim 7, wherein the current blocking layer is formed of an undoped semiconductor material.

9. The method of claim 7, wherein the forming of the current blocking layer comprises:
forming a semiconductor material layer; and
implanting impurity ions into the semiconductor material layer.

10. The method of claim 9, wherein the impurity ions are one of Zn and Si ions.

11. The method of claim 7, wherein the crystalline layer is formed of one of an AlGaN-based material and an InGaAlP-based material.

12. The laser diode of claim 2, further comprising a contact layer and an upper electrode, which are sequentially stacked on the current blocking layer.

13. The laser diode of claim 3, further comprising a contact layer and an upper electrode, which are sequentially stacked on the current blocking layer.

14. The laser diode of claim 4, further comprising a contact layer and an upper electrode, which are sequentially stacked on the current blocking layer.

15. The laser diode of claim 2, wherein the crystalline layer is formed of one of an AlGaN-based material and an InGaAlP-based material.

16. The laser diode of claim 3, wherein the crystalline layer is formed of one of an AlGaN-based material and an InGaAlP-based material.

17. The laser diode of claim 4, wherein the crystalline layer is formed of one of an AlGaN-based material and an InGaAlP-based material.

18. The method of claim 8, wherein the crystalline layer is formed of one of an AlGaN-based material and an InGaAlP-based material.

19. The method of claim 9, wherein the crystalline layer is formed of one of an AlGaN-based material and an InGaAlP-based material.

20. The method of claim 10, wherein the crystalline layer is formed of one of an AlGaN-based material and an InGaAlP-based material.
